(19) United States
(12) Patent Application Publication
(10) Pub. No.: US 2020/0051485 A1
(43) Pub. Date: Feb. 13, 2020

(54) PIXEL STRUCTURE, DISPLAY SUBSTRATE, DISPLAY DEVICE AND DISPLAY METHOD

(71) Applicant: BOE TECHNOLOGY GROUP CO., LTD., Beijing (CN)

(72) Inventors: Wenqu LIU, Beijing (CN); Liwen DONG, Beijing (CN); Ning DANG, Beijing (CN); Zhijun LV, Beijing (CN)

(73) Assignee: BOE TECHNOLOGY GROUP CO., LTD., Beijing (CN)

(21) Appl. No.: 16/340,564

(22) PCT Filed: May 14, 2018
(86) PCT No.: PCT/CN2018/086703

§ 371 Date: Apr. 9, 2019

(30) Foreign Application Priority Data
Jun. 7, 2017 (CN) 201710423173.8

(51) Int. Cl. G09G 3/20; H01L 27/12

(52) U.S. Cl. CPC G09G 3/2074; G09G 2300/0452; H01L 27/1214

(57) ABSTRACT

A pixel structure, a display substrate, a display device and a display method are provided. The pixel structure includes multiple pixel units. Each pixel unit includes one rhombus sub-pixel and four congruent regular hexagon sub-pixels. The four congruent regular hexagon sub-pixels are arranged around the rhombus sub-pixel.

### CROSS-REFERENCE TO RELATED APPLICATION

This application claims a priority to Chinese Patent Application No. 201710423173.8 filed on Jun. 7, 2017, the disclosure of which is incorporated in its entirety by reference herein.

### TECHNICAL FIELD

The present disclosure relates to the field of display technology, in particular to a pixel structure, a display substrate, a display device and a display method.

### BACKGROUND

Currently, pixel structure usually adopts RGB three-color system where one pixel unit includes sub-pixels of colors of red (R), green (G) and blue (B). Color and brightness displayed by the pixel unit may be controlled by controlling components of the three colors RGB respectively corresponding to the three sub-pixels in the pixel unit. In a conventional pixel structure, the sub-pixels are usually rectangular and cannot meet requirement on diversity of the pixel structure.

### SUMMARY

In view of the above, the present disclosure provides a pixel structure, a display substrate, a display device and a display method.

The present disclosure provides a pixel structure, including multiple pixel units. Each pixel unit of the multiple pixel units includes one rhombus sub-pixel and four congruent regular hexagon sub-pixels. The four congruent regular hexagon sub-pixels are arranged around the rhombus sub-pixel.

Optionally, the four regular hexagon sub-pixels are arranged in two rows and two columns. Two regular hexagon sub-pixels in an identical row or an identical column share an identical side, two regular hexagon sub-pixels in an identical column or an identical row share an identical vertex, and the rhombus sub-pixel shares each of four sides with one of the four regular hexagon sub-pixels.

Optionally, each pixel unit includes eight triangle sub-pixels, the rhombus sub-pixel, the four regular hexagon sub-pixels and the eight triangle sub-pixels together form a rectangle, the eight triangle sub-pixels are arranged around the four regular hexagon sub-pixels, and each triangle sub-pixel and the regular hexagon sub-pixel adjacent to the each triangle sub-pixel share an identical side. The eight triangle sub-pixels are arranged in three rows, a first row and a third row each include three triangle sub-pixels, a second triangle sub-pixel in the first row and a second triangle sub-pixel in the third row form an entire rhombus, a first sub-pixel and a third sub-pixel in the first row and a first sub-pixel and a third sub-pixel in the third row form an entire rhombus, a second row includes two triangle sub-pixels, and the two triangle sub-pixels in the second row form an entire rhombus.

Optionally, sub-pixels in the pixel substrate are arranged in multiple rows, and sub-pixels in a first row and a last row are the triangle sub-pixels; in even-numbered rows other than the first and the last rows, the sub-pixels are the regular hexagon sub-pixels; and in odd-numbered rows other than the first and the last rows, a first sub-pixel and a last sub-pixel are the triangle sub-pixels, and the other sub-pixels are the rhombus sub-pixels.

Optionally, the four regular hexagon sub-pixels at least include a red sub-pixel, a green sub-pixel and a blue sub-pixel.

Optionally, the four regular hexagon sub-pixels include two red sub-pixels or two green sub-pixels or two blue sub-pixels.

Optionally, in the four regular hexagon sub-pixels, the sub-pixels of the same color are arranged diagonally.

Optionally, the multiple regular hexagon sub-pixels in an identical row or an identical column include red sub-pixels, green sub-pixels and blue sub-pixels, three adjacent sub-pixels in the identical row or the identical column form one group, each group includes one red sub-pixel, one green sub-pixel and one blue sub-pixel, and the red sub-pixels, the green sub-pixels and the blue sub-pixels in respective groups are arranged in an identical sequence.

Optionally, the rhombus sub-pixel is a white sub-pixel or a yellow sub-pixel.

Optionally, each pixel unit includes eight triangle sub-pixels. The rhombus sub-pixel, the four regular hexagon sub-pixels and the eight triangle sub-pixels together form a rectangle. The eight triangle sub-pixels are arranged around the four regular hexagon sub-pixels, and each triangle sub-pixel and the regular hexagon sub-pixel adjacent to the each triangle sub-pixel share an identical side. The eight triangle sub-pixels are arranged in three rows, a first row and a third row each include three triangle sub-pixels, a second triangle sub-pixel in the first row and a second triangle sub-pixel in the third row form an entire rhombus, a first sub-pixel and a third sub-pixel in the first row and a first sub-pixel and a third sub-pixel in the third row form an entire rhombus, a second row includes two triangle sub-pixels, and the two triangle sub-pixels in the second row form an entire rhombus. A color of the triangle sub-pixels is identical to a color of the rhombus sub-pixel.

The present disclosure further provides a display substrate, including the above-described pixel structure.

The present disclosure further provides a display device, including the above-described display substrate.

The present disclosure further provides a display method, applied to the above-described display device, including: dividing sub-pixels of the display substrate into multiple display units, each display unit corresponding to one pixel unit; and displaying with each display unit using as one unit.

The present disclosure further provides a display method, applied to the above-described display device, including: dividing sub-pixels of the display substrate into multiple display units, each display unit at least including three regular hexagon sub-pixels in an identical row and at least one half-rhombus sub-pixel; and displaying with each display unit using as one unit.

Beneficial effects of the technical solutions of the embodiments of the present disclosure are given as follows. The pixel structure in the embodiments of the present disclosure includes regular hexagon sub-pixels and rhombus sub-pixels, which differ from conventional rectangle sub-pixels and can meet requirement on diversity of the pixel structure. In addition, area utilization is relatively high with cooperation of the regular hexagon sub-pixels and the rhombus sub-pixels; hence, a display device having such pixel structure may have improved aperture ratio and improved brightness of unit area.

### BRIEF DESCRIPTION OF THE DRAWINGS

FIG. 1 is a schematic view of a pixel structure according to a first embodiment of the present disclosure;

FIG. 2 is a schematic structural view of a pixel unit in the pixel structure according to the first embodiment of the present disclosure;

FIG. 3 is a schematic view of a pixel structure according to a second embodiment of the present disclosure;

FIG. 4 is a schematic structural view of a pixel unit in the pixel structure according to the second embodiment of the present disclosure;

FIG. 5 is a schematic view of a pixel structure according to a third embodiment of the present disclosure;

FIG. 6 is a schematic structural view of a pixel unit in the pixel structure according to the third embodiment of the present disclosure;

FIG. 7 is a schematic view of a pixel structure according to a fourth embodiment of the present disclosure;

FIG. 8 is a schematic view of a pixel structure according to a fifth embodiment of the present disclosure;

FIG. 9 is a schematic view of a pixel structure according to a sixth embodiment of the present disclosure; and

FIG. 10 is a schematic view of a pixel structure according to a seventh embodiment of the present disclosure.

### DETAILED DESCRIPTION

To better clarify objectives, technical solutions and advantages of embodiments of the present disclosure, the technical solutions in the embodiments of the present disclosure are described in a clear and complete way in conjunction with drawings in the embodiments of the present disclosure. Apparently, the described embodiments are merely a part of rather than all of the embodiments of the present disclosure. All other embodiments obtained by the ordinary skilled in the art based on the described embodiments of the present disclosure fall within protection scope of the present disclosure.

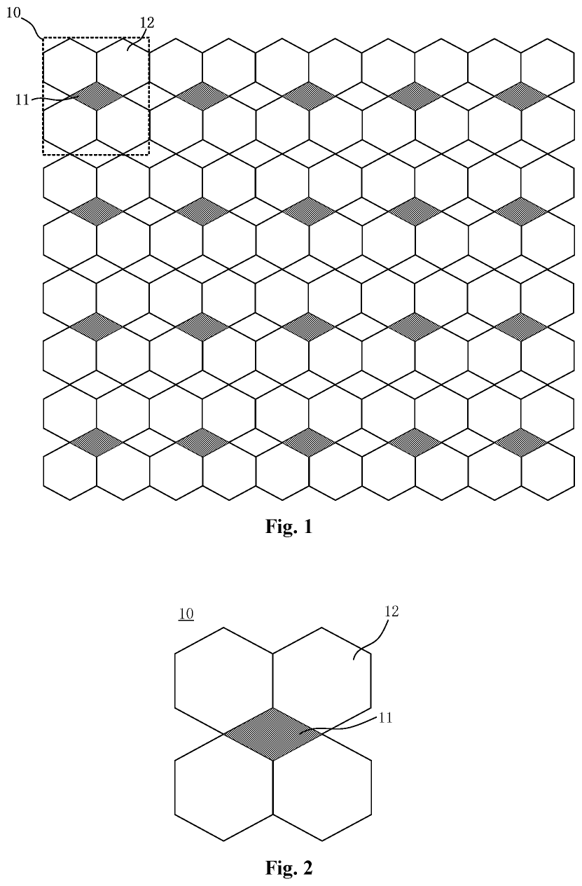

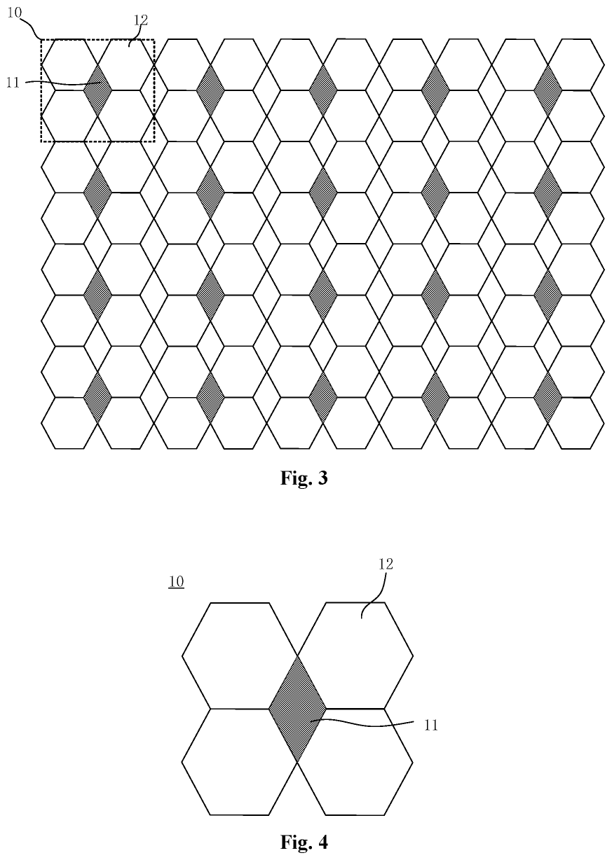

A pixel structure is provided according to an embodiment of the present disclosure. With reference to FIG. 1 and FIG. 2, the pixel structure includes multiple pixel units 10, each pixel unit 10 includes one rhombus sub-pixel 11 and four congruent regular hexagon sub-pixels 12, and the four congruent regular hexagon sub-pixels 12 are arranged around the rhombus sub-pixel 11.

The pixel structure in the embodiment of the present disclosure includes regular hexagon sub-pixels and rhombus sub-pixels, which differ from conventional rectangle sub-pixels and can meet requirement on diversity of the pixel structure. In addition, area utilization is relatively high with cooperation of the regular hexagon sub-pixels and the rhombus sub-pixels; hence, a display device having such pixel structure may have improved aperture ratio and improved brightness of unit area.

As shown in FIG. 2, in a first embodiment of the present disclosure, four regular hexagon sub-pixels 12 in one pixel unit 10 are arranged in two rows and two columns. Two regular hexagon sub-pixels 12 in an identical row share an identical side, two regular hexagon sub-pixels 12 in an identical column share an identical vertex, and the rhombus sub-pixel 11 shares each of its four sides with one of the four regular hexagon sub-pixels 12, that is, a length of the sides of the rhombus sub-pixel 11 is identical to a length of sides of the regular hexagon sub-pixels 12. In such structure, the rhombus sub-pixel closely fits with the four regular hexagon sub-pixels and therefore area utilization is improved as high as possible.

In the embodiment, six interior angles of the regular hexagon sub-pixel are all 120 degrees, the rhombus sub-pixel has two interior angles of 120 degrees and two interior angles of 60 degrees, and an area of the rhombus sub-pixel is one third of an area of the regular hexagon sub-pixel.

In some other embodiments of the present disclosure, the rhombus sub-pixel and the four regular hexagon sub-pixels in the pixel unit 10 may be arranged in other ways. In a second embodiment of the present disclosure, as shown in FIG. 3 and FIG. 4, four regular hexagon sub-pixels 12 in one pixel unit 10 are arranged in two rows and two columns. Two regular hexagon sub-pixels 12 in an identical row share an identical vertex, two regular hexagon sub-pixels 12 in an identical column share an identical side, and the rhombus sub-pixel 11 shares each of its four sides with one of the four regular hexagon sub-pixels 12. The pixel unit as shown in FIG. 4 is acquired by rotating the pixel unit as shown in FIG. 2 by 90 degrees.

In some other embodiments of the present disclosure, the rhombus sub-pixel and the four regular hexagon sub-pixels in the pixel unit 10 may be arranged in other ways, which are not enumerated herein.

It may be found from the embodiments as shown in FIG. 1 and FIG. 3 that, there still exist blank rhombus regions between the sub-pixels where no sub-pixel is arranged, so area utilization is not sufficient.

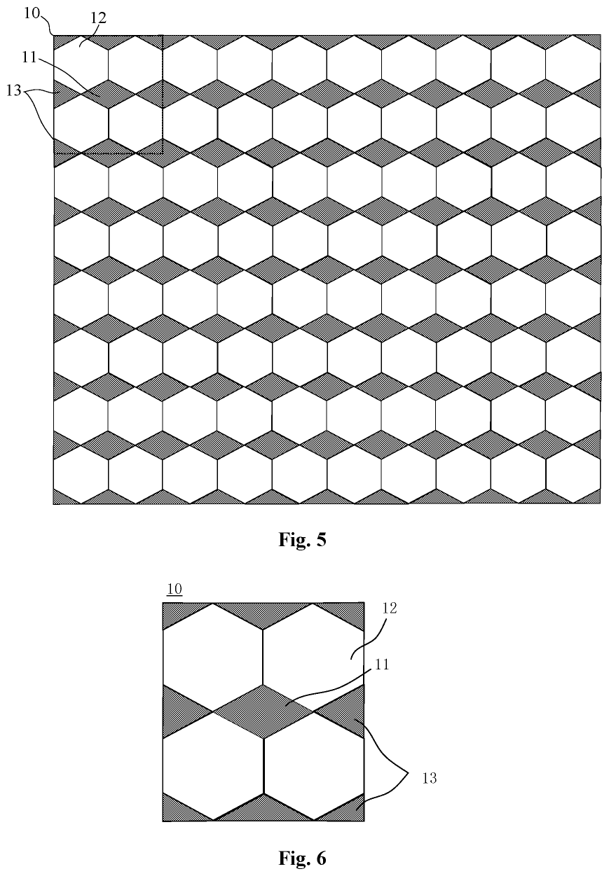

To further improve the area utilization, as shown in FIG. 5 and FIG. 6, in some embodiments of the present disclosure, each pixel unit may include eight triangle sub-pixels 13 in addition to one rhombus sub-pixel 11 and four congruent regular hexagon sub-pixels 12 surrounding the rhombus sub-pixel 11. The rhombus sub-pixel 11, the four regular hexagon sub-pixels 12 and the eight triangle sub-pixels 13 together form a rectangle.

Optionally, the rhombus sub-pixel 11, the four regular hexagon sub-pixels 12 and the eight triangle sub-pixels 13 together form a square.

In a third embodiment as shown in FIG. 5 and FIG. 6, the eight triangle sub-pixels 13 are arranged around the four regular hexagon sub-pixels. Each triangle sub-pixel 13 and an adjacent regular hexagon sub-pixel share an identical side. The eight triangle sub-pixels 13 are arranged in three rows, a first row and a third row each include three triangle sub-pixels 13. A second triangle sub-pixel 13 in the first row and a second triangle sub-pixel 13 in the third row form an entire rhombus. A first sub-pixel 13 and a third sub-pixel 13 in the first row and a first sub-pixel 13 and a third sub-pixel 13 in the third row form an entire rhombus. A second row includes two triangle sub-pixels 13 and the two triangle sub-pixels 13 in the second row form an entire rhombus. The above rhombus formed by two or more triangles has an identical shape and area to the rhombus sub-pixel in the embodiments of the present disclosure.

As shown in FIG. 5, in the embodiment of the present disclosure, multiple sub-pixels in the pixel substrate are arranged in multiple rows. Sub-pixels in a first row and a last row are triangle sub-pixels 13. Except for the first and the last rows, sub-pixels in an even-numbered row are regular hexagon sub-pixels. Except for the first and the last rows, a first sub-pixel and a last sub-pixel in an odd-numbered row are triangle sub-pixels 13 and the other sub-pixels in the odd-numbered row are rhombus sub-pixels 11. That is to say, triangle sub-pixels in adjacent pixel units may form an entire rhombus sub-pixel.

The pixel substrate according to the embodiments of the present disclosure can effectively improve the area utilization.

How the sub-pixels in the pixel structure are arranged is described in the foregoing embodiments. How to set colors of the sub-pixels in the pixel structure is described hereinafter.

Currently, the sub-pixels are usually set in colors of red, green and blue. In an embodiment of the present disclosure, optionally, four regular hexagon sub-pixels 12 of one pixel unit 10 at least include one red sub-pixel, one green sub-pixel and one blue sub-pixel.

That is, among the four regular hexagon sub-pixels 12 of one pixel unit 10, one is a red sub-pixel (labeled as R), one is a green sub-pixel (labeled as G) and one is a blue sub-pixel (labeled as B). The last sub-pixel may be set according to needs.

For example, if a display device does not have sufficient red light, the last sub-pixel may be a red sub-pixel; if the display device does not have sufficient green light, the last sub-pixel may be a green sub-pixel; and if the display device does not have sufficient blue light, the last sub-pixel may be a blue sub-pixel. That is, the four regular hexagon sub-pixels 12 of one pixel unit 10 may include two red sub-pixels, two green sub-pixels or two blue sub-pixels, to make up for insufficient display of the sub-pixel of a certain color.

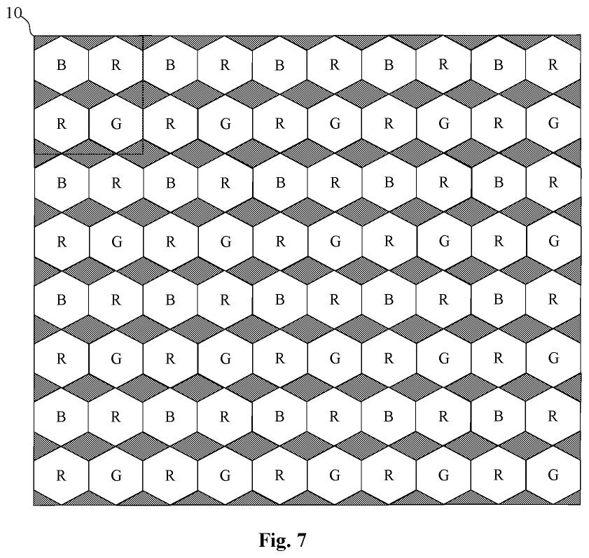

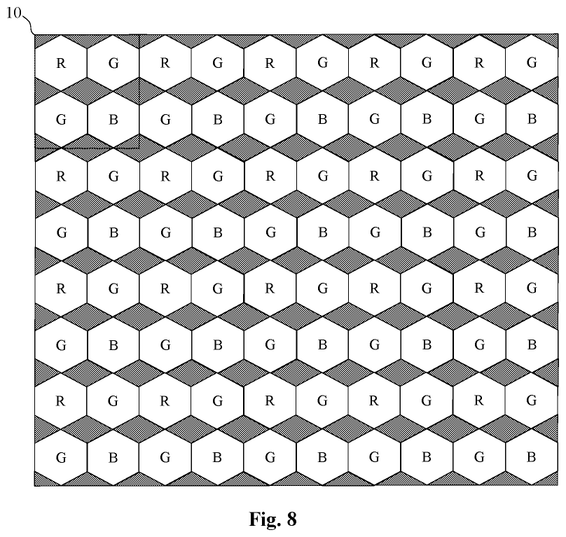

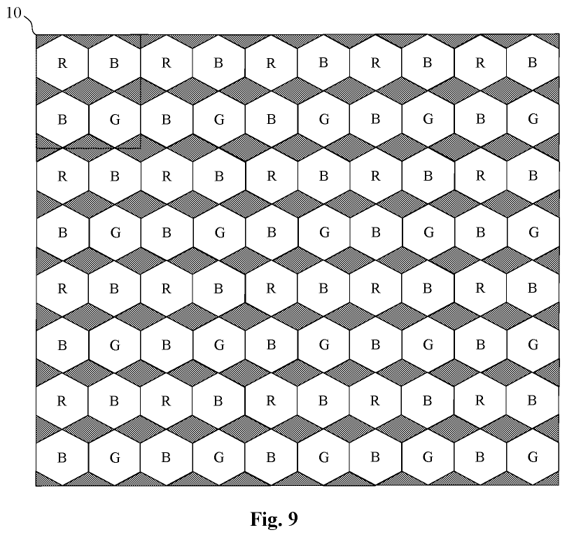

Furthermore, optionally, among the four regular hexagon sub-pixels 12 of one pixel unit 10, sub-pixels of the same color are arranged diagonally to provide more uniform colors, which may be understood with reference to FIG. 7, FIG. 8 and FIG. 9.

In embodiments shown in FIG. 7, FIG. 8 and FIG. 9, the respective pixel units 10 utilize the same way to set colors of the four regular hexagon sub-pixels therein. Multiple regular hexagon sub-pixels in an identical row or an identical column only include sub-pixels of two colors and the sub-pixels of the two colors are alternately arranged.

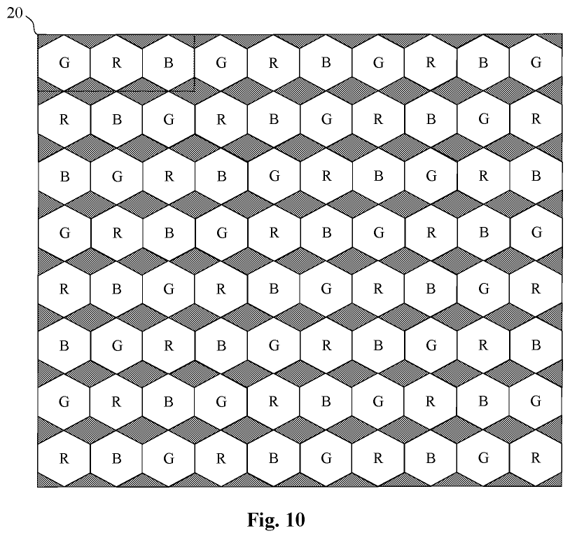

In some other embodiments of the present disclosure, colors of the sub-pixels in the pixel structure may be arranged in other ways. In an embodiment as shown in FIG. 10, multiple regular hexagon sub-pixels in an identical row include sub-pixels of three colors of red, green and blue, three adjacent sub-pixels in an identical row form one group, each group includes one red sub-pixel, one green sub-pixel and one blue sub-pixel, and the red sub-pixels, the green sub-pixels and the blue sub-pixels in respective groups are arranged in an identical sequence. In addition, multiple regular hexagon sub-pixels in an identical column include sub-pixels of three colors of red, green and blue, three adjacent sub-pixels in an identical column form one group, each group includes one red sub-pixel, one green sub-pixel and one blue sub-pixel, and the red sub-pixels, the green sub-pixels and the blue sub-pixels in respective groups are arranged in an identical sequence. By adopting such arranging manner, a case that only one color exists in the row direction and the column direction is avoided, generated color is more uniform, color mixture performance is improved and marginal error is avoided.

In some other embodiments of the present disclosure, the sub-pixels of the three colors are arranged only in the row direction or only in the column direction. That is. multiple regular hexagon sub-pixels in an identical row or an identical column include sub-pixels of three colors of red, green and blue, three adjacent sub-pixels in an identical row or an identical column form one group, each group includes one red sub-pixel, one green sub-pixel and one blue sub-pixel, and the red sub-pixels, the green sub-pixels and the blue sub-pixels in respective groups are arranged in an identical sequence.

To improve the brightness, according to an embodiment of the present disclosure, the rhombus sub-pixel 11 in the pixel structure may be a white sub-pixel or a yellow sub-pixel.

In a case that the pixel unit includes the triangle sub-pixels 13, the color of the triangle sub-pixels 13 may be identical to that of the rhombus sub-pixel, for example, the triangle sub-pixels 13 may be white sub-pixels or yellow sub-pixels.

A display substrate is further provided according to an embodiment of the present disclosure, where the display substrate includes the above-described pixel structure.

A display device is further provided according to an embodiment of the present disclosure, including the above-described display substrate. The display device may be a display panel, or may be a display component having a display panel and a driving circuit.

A display method is further provided according to an embodiment of the present disclosure, which is applied to the above display device.

The display method includes: step 101, dividing sub-pixels of the display substrate into multiple display units, each display unit corresponding to one pixel unit; and step 102, displaying with each display unit using as one unit.

The display method is applied to the following pixel structure. Colors of four regular hexagon sub-pixels in one pixel unit 10 are arranged in an identical manner to colors of four regular hexagon sub-pixels in each of the other pixel units 10. Multiple regular hexagon sub-pixels in an identical row and multiple regular hexagon sub-pixels in an identical column include sub-pixels of only two colors, and the sub-pixels of the two colors are arranged alternately. Reference may be made to, for example, the pixel structures according to embodiments shown in FIG. 7, FIG. 8 and FIG. 9.

Another display method is further provided according to an embodiment of the present disclosure, which is applied to the above-described display device.

The display method includes: step 201, dividing sub-pixels of the display substrate into multiple display units, each display unit at least including three regular hexagon sub-pixels in an identical row and at least one half-rhombus sub-pixel; and step 202, displaying with each display unit using as one unit.

The display method is applied to the following pixel structure. Multiple regular hexagon sub-pixels in an identical row or an identical column include sub-pixels of three colors of red, green and blue, three adjacent sub-pixels in an identical row or an identical column form one group, each group includes one red sub-pixel, one green sub-pixel and one blue sub-pixel, and the red sub-pixels, the green sub-pixels and the blue sub-pixels in respective groups are arranged in an identical sequence. Reference may be made to, for example, the pixel structure as shown in FIG. 10.

When the pixel structure as shown in FIG. 10 performs displaying, each display unit 20 includes three regular hexagon sub-pixels in an identical row and eight triangle sub-pixels surrounding the three regular hexagon sub-pixels. Among the eight triangle sub-pixels, each of at least partial triangle sub-pixels is a half of a rhombus sub-pixel located at a periphery of the three regular hexagon sub-pixels, and each of at least partial triangle sub-pixels is a quarter of a rhombus sub-pixel located at the periphery of the three regular hexagon sub-pixels.

The pixel structures according to the foregoing embodiments of the present disclosure may be applied to a liquid crystal display panel or an organic light-emitting diode display substrate.

Unless otherwise defined, technical terms or scientific terms used in the present disclosure refer to common meanings understood by the ordinary skilled in the art to which the present disclosure relates. Terms of “first”, “second” and the like used in the present disclosure do not indicate any order, quantity or importance, and they are merely used to distinguish different components. In addition, terms such as “a” and “an” do not indicate the quantity but mean there exists at least one. Terms such as “connected to” and “coupled to” are not limited to physical or mechanical connections but can include direct or indirect electrical connections. Terms such as “above”, “below”, “left” and “right” only indicate relative position relationships; and in a case that an absolute position of a described object changes, relative position relationships with respect to the described object may change correspondingly.

Optional embodiments are described hereinabove. It should be noted that various improvements and polishments can be made by the ordinary skilled in the art without departing from the principle of the present disclosure. The improvements and polishments all fall within the protection scope of the present disclosure.

1. A pixel structure, comprising a plurality of pixel units, wherein each pixel unit of the plurality of pixel units comprises one rhombus sub-pixel and four congruent regular hexagon sub-pixels, and the four congruent regular hexagon sub-pixels are arranged around the rhombus sub-pixel.

2. The pixel structure according to claim 1, wherein the four regular hexagon sub-pixels are arranged in two rows and two columns, two regular hexagon sub-pixels in an identical row or an identical column share an identical side, two regular hexagon sub-pixels in an identical column or an identical row share an identical vertex, and the rhombus sub-pixel shares each of four sides with one of the four regular hexagon sub-pixels;
wherein each pixel unit comprises eight triangle sub-pixels, the rhombus sub-pixel, the four regular hexagon sub-pixels and the eight triangle sub-pixels together form a rectangle, the eight triangle sub-pixels are arranged around the four regular hexagon sub-pixels, and each triangle sub-pixel and the regular hexagon sub-pixel adjacent to the each triangle sub-pixel share an identical side; wherein the eight triangle sub-pixels are arranged in three rows, a first row and a third row each comprise three triangle sub-pixels, a second triangle sub-pixel in the first row and a second triangle sub-pixel in the third row form an entire rhombus, a first sub-pixel and a third sub-pixel in the first row and a first sub-pixel and a third sub-pixel in the third row form an entire rhombus, a second row comprises two triangle sub-pixels, and the two triangle sub-pixels in the second row form an entire rhombus.

3. The pixel structure according to claim 2, wherein sub-pixels in the pixel substrate are arranged in a plurality of rows, and sub-pixels in a first row and a last row are the triangle sub-pixels; in even-numbered rows other than the first and the last rows, the sub-pixels are the regular hexagon sub-pixels; and in odd-numbered rows other than the first and the last rows, a first sub-pixel and a last sub-pixel are the triangle sub-pixels, and the other sub-pixels are the rhombus sub-pixels.

4. The pixel structure according to claim 1, wherein the four regular hexagon sub-pixels comprise a red sub-pixel, a green sub-pixel and a blue sub-pixel, the four regular hexagon sub-pixels comprise two red sub-pixels or two green sub-pixels or two blue sub-pixels, and the sub-pixels of the same color are arranged diagonally.

5. The pixel structure according to claim 4, wherein the plurality of regular hexagon sub-pixels in an identical row or an identical column comprises red sub-pixels, green sub-pixels and blue sub-pixels, three adjacent sub-pixels in the identical row or the identical column form one group, each group comprises one red sub-pixel, one green sub-pixel and one blue sub-pixel, and the red sub-pixels, the green sub-pixels and the blue sub-pixels in respective groups are arranged in an identical sequence.

6. The pixel structure according to claim 4, wherein each pixel unit comprises eight triangle sub-pixels, the rhombus sub-pixel, the four regular hexagon sub-pixels and the eight triangle sub-pixels together form a rectangle, the eight triangle sub-pixels are arranged around the four regular hexagon sub-pixels, and each triangle sub-pixel and the regular hexagon sub-pixel adjacent to the each triangle sub-pixel share an identical side; wherein the eight triangle sub-pixels are arranged in three rows, a first row and a third row each comprise three triangle sub-pixels, a second triangle sub-pixel in the first row and a second triangle sub-pixel in the third row form an entire rhombus, a first sub-pixel and a third sub-pixel in the first row and a first sub-pixel and a third sub-pixel in the third row form an entire rhombus, a second row comprises two triangle sub-pixels, and the two triangle sub-pixels in the second row form an entire rhombus;
wherein the rhombus sub-pixel is a white sub-pixel or a yellow sub-pixel, and a color of the triangle sub-pixels is identical to a color of the rhombus sub-pixel.

7. A display substrate, comprising the pixel structure according to claim 1.

8. A display device, comprising the display substrate according to claim 7.

9. A display method, applied to the display device according to claim 8, comprising: dividing sub-pixels of the display substrate into a plurality of display units, each display unit corresponding to one pixel unit; and displaying with each display unit using as one unit.

10. A display method, applied to the display device according to claim 8, comprising: dividing sub-pixels of the display substrate into a plurality of display units, each display unit at least comprising three regular hexagon sub-pixels in an identical row and at least one half-rhombus sub-pixel; and displaying with each display unit using as one unit.

11. The pixel structure according to claim 2, wherein the four regular hexagon sub-pixels comprise a red sub-pixel, a green sub-pixel and a blue sub-pixel, the four regular hexagon sub-pixels comprise two red sub-pixels or two green sub-pixels or two blue sub-pixels, and the sub-pixels of the same color are arranged diagonally.

12. The pixel structure according to claim 3, wherein the four regular hexagon sub-pixels comprise a red sub-pixel, a green sub-pixel and a blue sub-pixel, the four regular hexagon sub-pixels comprise two red sub-pixels or two green sub-pixels or two blue sub-pixels, and the sub-pixels of the same color are arranged diagonally.

13. The display substrate according to claim 7, wherein the four regular hexagon sub-pixels are arranged in two rows and two columns, two regular hexagon sub-pixels in an identical row or an identical column share an identical side, two regular hexagon sub-pixels in an identical column or an identical row share an identical vertex, and the rhombus sub-pixel shares each of four sides with one of the four regular hexagon sub-pixels;
wherein each pixel unit comprises eight triangle sub-pixels, the rhombus sub-pixel, the four regular hexagon sub-pixels and the eight triangle sub-pixels together form a rectangle, the eight triangle sub-pixels are arranged around the four regular hexagon sub-pixels, and each triangle sub-pixel and the regular hexagon sub-pixel adjacent to the each triangle sub-pixel share an identical side; wherein the eight triangle sub-pixels are arranged in three rows, a first row and a third row each comprise three triangle sub-pixels, a second triangle sub-pixel in the first row and a second triangle sub-pixel in the third row form an entire rhombus, a first sub-pixel and a third sub-pixel in the first row and a first sub-pixel and a third sub-pixel in the third row form an entire rhombus, a second row comprises two triangle sub-pixels, and the two triangle sub-pixels in the second row form an entire rhombus.

14. The display substrate according to claim 13, wherein sub-pixels in the pixel substrate are arranged in a plurality of rows, and sub-pixels in a first row and a last row are the triangle sub-pixels; in even-numbered rows other than the first and the last rows, the sub-pixels are the regular hexagon sub-pixels; and in odd-numbered rows other than the first and the last rows, a first sub-pixel and a last sub-pixel are the triangle sub-pixels, and the other sub-pixels are the rhombus sub-pixels.

15. The display substrate according to claim 7, wherein the four regular hexagon sub-pixels comprise a red sub-pixel, a green sub-pixel and a blue sub-pixel, the four regular hexagon sub-pixels comprise two red sub-pixels or two green sub-pixels or two blue sub-pixels, and the sub-pixels of the same color are arranged diagonally.

16. The display substrate according to claim 15, wherein the plurality of regular hexagon sub-pixels in an identical row or an identical column comprises red sub-pixels, green sub-pixels and blue sub-pixels, three adjacent sub-pixels in the identical row or the identical column form one group, each group comprises one red sub-pixel, one green sub-pixel and one blue sub-pixel, and the red sub-pixels, the green sub-pixels and the blue sub-pixels in respective groups are arranged in an identical sequence.

17. The display substrate according to claim 15, wherein each pixel unit comprises eight triangle sub-pixels, the rhombus sub-pixel, the four regular hexagon sub-pixels and the eight triangle sub-pixels together form a rectangle, the eight triangle sub-pixels are arranged around the four regular hexagon sub-pixels, and each triangle sub-pixel and the regular hexagon sub-pixel adjacent to the each triangle sub-pixel share an identical side; wherein the eight triangle sub-pixels are arranged in three rows, a first row and a third row each comprise three triangle sub-pixels, a second triangle sub-pixel in the first row and a second triangle sub-pixel in the third row form an entire rhombus, a first sub-pixel and a third sub-pixel in the first row and a first sub-pixel and a third sub-pixel in the third row form an entire rhombus, a second row comprises two triangle sub-pixels, and the two triangle sub-pixels in the second row form an entire rhombus;
wherein the rhombus sub-pixel is a white sub-pixel or a yellow sub-pixel, and a color of the triangle sub-pixels is identical to a color of the rhombus sub-pixel.
